(19) United States
(12) Patent Application Publication
(10) Pub. No.: US 2024/0388277 A1
(43) Pub. Date: Nov. 21, 2024

(54) ELECTRONIC CIRCUIT

(71) Applicant: Innolux Corporation, Miaoli County (TW)

(72) Inventors: Ming-Chun Tseng, Miaoli County (TW); Kung-Chen Kuo, Miaoli County (TW); Lien-Hsiang Chen, Miaoli County (TW); Yong-Zhi Liu, Miaoli County (TW); Po-Syun Chen, Miaoli County (TW)

(73) Assignee: Innolux Corporation, Miaoli County (TW)

(21) Appl. No.: 18/632,231

(22) Filed: Apr. 10, 2024

Related U.S. Application Data
(60) Provisional application No. 63/467,009, filed on May 17, 2023.

(30) Foreign Application Priority Data
Jan. 11, 2024 (CN) 202410041672.0

(51) Int. Cl. H03K 3/011; G09G 3/20; H01Q 23/00

(52) U.S. Cl. CPC H03K 3/011; G09G 3/20; H01Q 23/00

(57) ABSTRACT

An electronic circuit is provided. The electronic circuit includes an electronic element, a driving transistor, a first emitting transistor, and at least one capacitor. A first terminal of the driving transistor is coupled to a power voltage. The power voltage is used to drive the electronic element via the driving transistor. A first terminal of the first emitting transistor is coupled to a second terminal of the driving transistor. A second terminal of the first emitting transistor is coupled to the electronic element. A first terminal of the at least one capacitor is coupled to a gate terminal of the driving transistor. When the electronic element is driven, a second terminal of the at least one capacitor receives the power voltage.

### CROSS-REFERENCE TO RELATED APPLICATION

This application claims the priority benefits of U.S. provisional application Ser. No. 63/467,009, filed on May 17, 2023, and China application serial no. 202410041672.0, filed on Jan. 11, 2024. The entirety of each of the above-mentioned patent applications is hereby incorporated by reference herein and made a part of this specification.

### BACKGROUND

### Technical Field

The disclosure relates to an electronic circuit, and in particular to an electronic circuit having a power compensation function.

### Description of Related Art

Generally, an electronic circuit may include a driving transistor and an electronic element. The first terminal of the driving transistor receives a power voltage. The second terminal of the driving transistor is connected to the electronic element. The gate terminal of the driving transistor receives a signal. The driving transistor may drive the electronic element based on the power voltage and the signal. However, when the power voltage ripples or fluctuates, the voltage difference between the gate terminal and the first terminal of the driving transistor is changed and the switching state of the driving transistor is affected. Therefore, the operation of the electronic element is relatively unstable due to the change in the power voltage. It may be seen from this that how to provide an electronic circuit capable of compensating the power voltage is one of the research focuses of those skilled in the art.

### SUMMARY

The disclosure is directed to an electronic circuit capable of compensating a power voltage.

According to an embodiment of the disclosure, an electronic circuit includes an electronic element, a driving transistor, a first emitting transistor, and at least one capacitor. The power voltage is used to drive the electronic element via the driving transistor. A first terminal of the first emitting transistor is coupled to the power voltage. A second terminal of the first emitting transistor is coupled to the driving transistor. A first terminal of the at least one capacitor is coupled to a gate terminal of the driving transistor. When the electronic element is driven, a second terminal of the at least one capacitor receives the power voltage.

According to an embodiment of the disclosure, an electronic circuit includes an electronic element, a driving transistor, a first emitting transistor, and at least one capacitor. A first terminal of the driving transistor is coupled to a power voltage. The power voltage is used to drive the electronic element via the driving transistor. A first terminal of the first emitting transistor is coupled to a second terminal of the driving transistor. A second terminal of the first emitting transistor is coupled to the electronic element. A first terminal of the at least one capacitor is coupled to a gate terminal of the driving transistor. When the electronic element is driven, a second terminal of the at least one capacitor receives the power voltage.

Based on the above, the first terminal of the at least one capacitor is coupled to the gate terminal of the driving transistor. When the electronic element is driven, the second terminal of the at least one capacitor receives the power voltage. Therefore, when the power voltage is changed, the voltage value at the gate terminal of the driving transistor is also changed with the change in the power voltage. In this way, the switching state of the driving transistor is not affected by the change in the power voltage. In this way, the operation of the electronic element remains relatively stable even when the power voltage is changed.

### BRIEF DESCRIPTION OF THE DRAWINGS

FIG. 1 is a schematic diagram of an electronic circuit shown according to the first embodiment of the disclosure.

FIG. 2 is a signal timing diagram shown according to the first embodiment.

FIG. 3 is a schematic diagram of an electronic circuit shown according to the second embodiment of the disclosure.

FIG. 4 is a signal timing diagram shown according to the second embodiment.

FIG. 5 is a schematic diagram of an electronic circuit shown according to the third embodiment of the disclosure.

FIG. 6 is a signal timing diagram shown according to the third embodiment.

FIG. 7 is a schematic diagram of an electronic circuit shown according to the fourth embodiment.

FIG. 8 is a schematic diagram of an electronic circuit shown according to the fifth embodiment.

FIG. 9 is a schematic diagram of an electronic circuit shown according to the sixth embodiment.

FIG. 10 is a schematic diagram of an electronic circuit shown according to the seventh embodiment.

### DESCRIPTION OF THE EMBODIMENTS

The disclosure may be understood by referring to the following detailed description taken in conjunction with the accompanying drawings as described below. It should be noted that, for purposes of clarity and easy understanding by readers, each drawing of the disclosure depicts a portion of an electronic device, and some elements in each drawing may not be drawn to scale. In addition, the number and the size of each device depicted in the drawings are illustrative and not intended to limit the scope of the disclosure.

Certain terms are used throughout the description and the following claims to refer to specific elements. As will be understood by those skilled in the art, manufacturers of electronic equipment may refer to elements by different names. This document does not intend to distinguish between elements that differ in name but not function. In the following description and in the claims, the terms “containing”, “including”, and “having” are used in an open-ended manner, and should therefore be construed to mean “containing but not limited to . . . ” Accordingly, when the terms “containing”, “including”, and/or “having” are used in the description of the disclosure, it will be indicated that there are corresponding features, regions, steps, operations, and/or elements, but not limited to there being one or a plurality of corresponding features, regions, steps, operations, and/or elements.

It should be understood that, when an element is referred to as being “coupled to”, “connected to”, or “conducted to” another element, the element may be directly connected to another element and an electrical connection may be established directly, or there may be an intermediate element between these elements for relaying an electrical connection (indirect electrical connection). In contrast, when an element is referred to as being “directly coupled to,” “directly connected to”, or “directly connected to” another element, there are no intervening elements present.

Although terms such as first, second, third, etc. may be used to describe various constituent elements, such constituent elements are not limited by these terms. The terms are used to distinguish a constituent element from other constituent elements in the specification. The claims may not use the same terms, but may use the terms first, second, third etc. with respect to the required order of the elements. Therefore, in the following description, a first constituent element may be a second constituent element in the claims.

In the disclosure, the method of measuring length, width, thickness, height, or area, or distance or spacing between elements may adopt optical microscopy (OM), scanning electron microscope (SEM), film thickness profiler (a-step), ellipsometer, or other suitable methods. Specifically, according to some embodiments, a cross-sectional structural image including the element to be measured may be obtained using a scanning electron microscope to measure the length, width, thickness, height, or area of each component, or the distance or spacing between elements, but the disclosure is not limited thereto.

An electronic device of the disclosure may include a display device, an antenna device, a sensing device, a light-emitting device, a touch display, a curved display, or a free shape display, but not limited to. The electronic device may include a bendable or flexible electronic device. The electronic device may, for example, include liquid crystal, light-emitting device, quantum dot (QD), fluorescence, phosphor, other suitable display media, or a combination of the above materials, but the disclosure is not limited thereto. The electronic element may include a passive element and an active element, such as a capacitor, a resistor, an inductor, a diode, a transistor, wherein the diode may include a light-emitting diode, a varactor diode, and a photodiode, but the disclosure is not limited thereto. The light-emitting diode may include, for example, an organic light-emitting diode (OLED), a mini LED, a micro LED, or a quantum dot LED (may include QLED or QDLED), or other suitable materials, or a combination of the above, but the disclosure is not limited thereto. The display device may include, for example, a tiling display device, but the disclosure is not limited thereto. The antenna device may be, for example, a liquid-crystal antenna or a varactor diode antenna device, but the disclosure is not limited thereto. The antenna device may include, for example, an antenna tiling device, but the disclosure is not limited thereto. It should be noted that the electronic device may be any arrangement and combination of the above, but the disclosure is not limited thereto. In addition, the shape of the electronic device may be rectangular, circular, polygonal, a shape having curved edges, or other suitable shapes. The electronic device may have a peripheral system such as a driving system, a control system, a light source system, etc. to support a display device, an antenna device, or a tiling device, but the disclosure is not limited thereto. The sensing device may include a camera, an infrared sensor, or a fingerprint sensor, etc., but the disclosure is not limited thereto. In some embodiments, the sensing device may further include a flashlight, an infrared (IR) light source, other sensors, electronic elements, or a combination thereof, but the disclosure is not limited thereto.

In the disclosure, the embodiments use “pixel” or “pixel unit” as a unit for describing a specific area including at least one functional circuit for at least one specific function. The area of a “pixel” depends on the unit used to provide a particular function, and adjacent pixels may share the same portions or conductive lines, but may also contain specific portions of themselves. For example, adjacent pixels may share the same scan line or the same data line, but a pixel may also have its own transistor or capacitor.

It should be noted that technical features in different embodiments described below may be replaced, reorganized, or mixed with each other to form another embodiment without departing from the spirit of the disclosure.

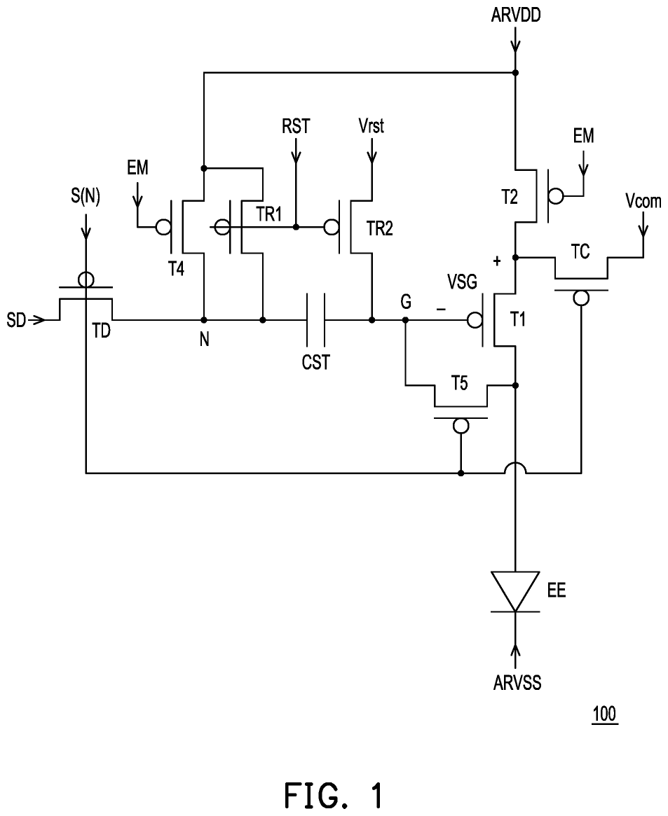

Please refer to FIG. 1. FIG. 1 is a schematic diagram of an electronic circuit shown according to the first embodiment of the disclosure. In the present embodiment, an electronic circuit 100 includes an electronic element EE, a driving transistor T1, an emitting transistor T2, and a capacitor CST. A power voltage ARVDD is used to drive the electronic element EE via the driving transistor T1. In particular, the gate terminal of the emitting transistor T2 receives an enabling signal EM, the first terminal of the emitting transistor T2 is coupled to the power voltage ARVDD, and the second terminal of the emitting transistor T2 is coupled to the first terminal of the driving transistor T1. The second terminal of the driving transistor T1 is coupled to the electronic element EE. The first terminal of the capacitor CST (i.e., a node G or an end point electrically connected to the node G) is coupled to the gate terminal of the driving transistor T1. When the electronic element EE is driven, the second terminal of the capacitor CST (i.e., the node N or an end point electrically connected to the node N) receives the power voltage ARVDD.

Taking the present embodiment as an example, the electronic element EE may be any form of light-emitting diode element, varactor diode, or photodiode, but the disclosure is not limited thereto. The electronic circuit 100 is, for example, a pixel circuit, a driving circuit, or a light-emitting circuit (but the disclosure is not limited thereto). The anode of the electronic element EE may be coupled to the second terminal of the driving transistor T1. The cathode of the electronic element EE may be coupled to the power voltage ARVSS.

It is worth mentioning here that the first terminal of the capacitor CST may be coupled to the gate terminal of the driving transistor T1. When the electronic element EE is driven based on the power voltage ARVDD, the second terminal of the capacitor CST may receive the power voltage ARVDD. Therefore, when the power voltage ARVDD is changed, the voltage value at the gate terminal of the driving transistor T1 is also changed with the change in the power voltage ARVDD. For example, when the power voltage ARVDD is decreased, the voltage value at the first terminal of the driving transistor T1 is decreased. The voltage value at the gate terminal of the driving transistor T1 is also decreased. When the power voltage ARVDD is increased, the voltage value at the first terminal of the driving transistor T1 is increased. The voltage value at the gate terminal of the driving transistor T1 is also increased. In other words, the voltage difference value VSG between the first terminal of the driving transistor T1 and the gate terminal of the driving transistor T1 is not affected by the change in the power voltage ARVDD.

Therefore, the switching state of the driving transistor T1 is not affected by the change in the power voltage ARVDD. The voltage value at the gate terminal of the driving transistor T1 is also changed with the change in the power voltage ARVDD. In this way, the operation of the electronic element EE remains relatively stable even when the power voltage ARVDD is changed.

Taking the present embodiment as an example, the electronic circuit 100 further includes an emitting transistor T4, a data transistor TD, compensation transistors T5 and TC, and reset transistors TR1 and TR2. In particular, the gate terminal of the transmitting transistor T4 receives the enabling signal EM. The first terminal of the emitting transistor T4 is coupled to the power voltage ARVDD. The second terminal of the emitting transistor T4 is coupled to the capacitor CST. Furthermore, the second terminal of the emitting transistor T4 is coupled to the second terminal of the capacitor CST. The first terminal of the data transistor TD receives a data signal SD. The second terminal of the data transistor TD is coupled to the second terminal of the capacitor CST. The gate terminal of the data transistor TD receives a scan signal S(N). The first terminal of a compensation transistor T5 is coupled to the second terminal of the driving transistor T1. The second terminal of the compensation transistor T5 is coupled to the gate terminal of the driving transistor T1. The gate terminal of the compensation transistor T5 receives the scan signal S(N). The first terminal of a compensation transistor TC receives a common voltage Vcom. The second terminal of the compensation transistor TC is coupled to the second terminal of the emitting transistor T2. The gate terminal of the compensation transistor TC receives the scan signal S(N).

The first terminal of the reset transistor TR1 is coupled to the power voltage ARVDD. The second terminal of the reset transistor TR1 is coupled to the second terminal of the capacitor CST (i.e., the node N or an end point electrically connected to the node N). The gate terminal of the reset transistor TR1 receives a reset signal RST. The first terminal of the reset transistor TR2 is coupled to a reset voltage Vrst. The second terminal of the reset transistor TR2 is coupled to the first terminal of the capacitor CST (i.e., the node G or an end point electrically connected to the node G). The gate terminal of the reset transistor TR2 receives the reset signal RST.

In the present embodiment, the driving transistor T1, the emitting transistors T2 and T4, the data transistor TD, the compensation transistors T5 and TC, and the reset transistors TR1 and TR2 may be implemented by P-type field-effect transistors respectively. However, the disclosure is not limited thereto.

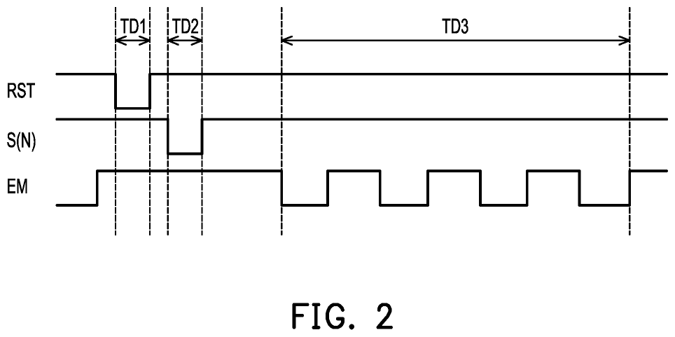

Please refer to both FIG. 1 and FIG. 2. FIG. 2 is a signal timing diagram shown according to the first embodiment. In the present embodiment, during a period TD1 (or reset period), the scan signal S(N) and the enabling signal EM respectively have high voltage levels. The reset signal RST has a low voltage level. The reset transistors TR1 and TR2 are turned on. The emitting transistors T2 and T4, the data transistor TD, and the compensation transistors T5 and TC are turned off. Therefore, the voltage value at the first terminal of the capacitor CST (i.e., the node G or an end point electrically connected to the node G) is substantially equal to the voltage value of the reset voltage Vrst. The voltage value at the second terminal of the capacitor CST (i.e., the node N or an end point electrically connected to the node N) is substantially equal to the voltage value of the power voltage ARVDD.

During a period TD2 (or data input period), the reset signal RST and the enabling signal EM respectively have high voltage levels. The scan signal S(N) has a low voltage level. The data transistor TD and the compensation transistors T5 and TC are turned on. The reset transistors TR1 and TR2 and the emitting transistors T2 and T4 are turned off. Therefore, the voltage value at the second terminal of the capacitor CST (i.e., the node N or an end point electrically connected to the node N) is substantially equal to the voltage value of the data signal SD. The electronic circuit 100 changes the voltage value at the gate terminal of the driving transistor T1 using the voltage value of the data signal SD based on the capacitive coupling of the capacitor CST. Since the compensation transistor T5 is turned on, the voltage value at the second terminal of the driving transistor T1 is substantially equal to the voltage value at the gate terminal of the driving transistor T1.

In addition, the voltage value at the first terminal of the driving transistor T1 is substantially equal to the voltage value of the common voltage Vcom. Therefore, the voltage difference value VSG between the voltage value at the first terminal (i.e., the source electrode) of the driving transistor T1 and the voltage value located at the gate terminal of the driving transistor T1 is determined. It should also be noted that during the period TD2, the power voltage ARVDD is changed due to the load change in the adjacent electronic circuit 100 or the load change in other electronic circuits. Compared with the power voltage ARVDD, the common voltage Vcom is relatively stable. Therefore, the electronic circuit 100 may provide a relatively stable voltage difference value VSG to the driving transistor T1 during the period TD2.

During a period TD3 (or driving period), the reset signal RST and the scan signal S(N) respectively have high voltage levels. The enabling signal EM has a duty cycle. The emitting transistors T2 and T4 perform a switching operation based on the duty cycle. The data transistor TD, the reset transistors TR1 and TR2, and the compensation transistors T5 and TC are turned off. Therefore, the driving transistor T1 drives the electronic element EE during the period TD3 using the power voltage ARVDD and the voltage value at the gate terminal of the driving transistor T1.

It should be noted that during the period TD3, the second terminal of the capacitor CST (i.e., the node N or an end point electrically connected to the node N) receives the power voltage ARVDD. When the power voltage ARVDD is decreased, the voltage value at the first terminal of the driving transistor T1 is decreased. The voltage value at the gate terminal of the driving transistor T1 is also decreased. When the power voltage ARVDD is increased, the voltage value at the first terminal of the driving transistor T1 is increased. The voltage value at the gate terminal of the driving transistor T1 is also increased. Therefore, the voltage difference value VSG of the driving transistor T1 is not affected by the change in the power voltage ARVDD.

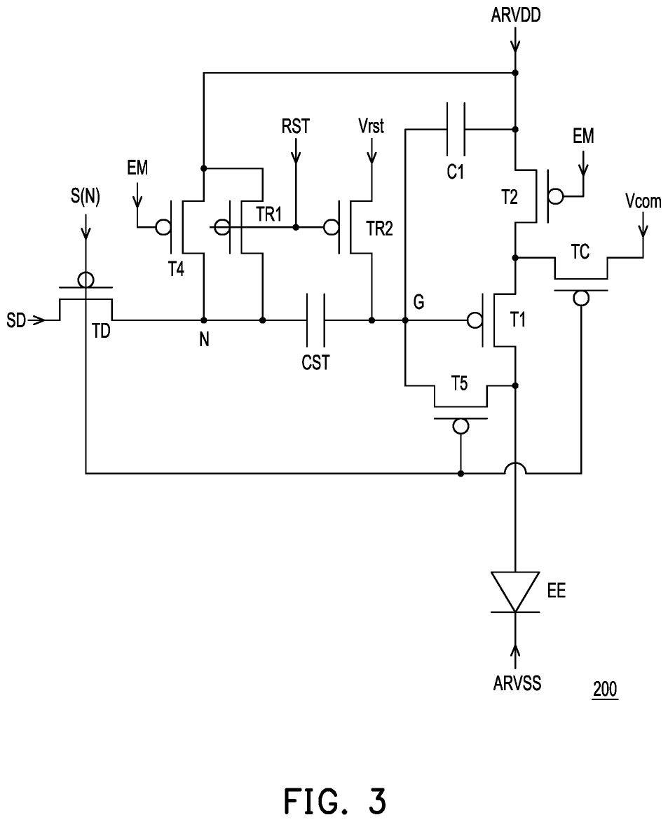

Please refer to FIG. 3. FIG. 3 is a schematic diagram of an electronic circuit shown according to the second embodiment of the disclosure. In the present embodiment, an electronic circuit 200 includes the electronic element EE, the driving transistor T1, the emitting transistors T2 and T4, the data transistor TD, the compensation transistors T5 and TC, the reset transistors TR1 and TR2, and the capacitors C1 and CST. The implementation method of the electronic element EE, the driving transistor T1, the emitting transistors T2 and T4, the data transistor TD, the compensation transistor T5 and TC, the reset transistors TR1 and TR2, and the capacitor CST is clearly explained in the embodiment of FIG. 1 and is therefore not repeated herein.

In the present embodiment, the first terminal of the capacitor C1 is coupled to receive the power voltage ARVDD. The second terminal of the capacitor C1 is coupled to the gate terminal of the driving transistor T1. Therefore, when the power voltage ARVDD is decreased, the voltage values at two terminals of the capacitor C1 are both decreased. When the power voltage ARVDD is increased, the voltage values at two terminals of the capacitor C1 are both increased. Therefore, the voltage difference value VSG of the driving transistor T1 is not affected by the change in the power voltage ARVDD.

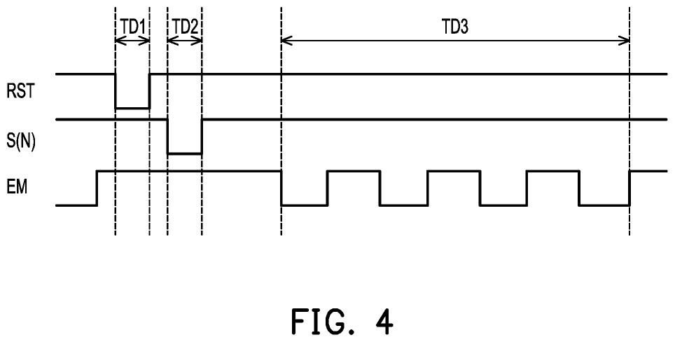

Please refer to FIG. 3 and FIG. 4. FIG. 4 is a signal timing diagram shown according to the second embodiment. In the present embodiment, the timing of the reset signal RST, the scan signal S(N), and the enabling signal EM of FIG. 4 is similar to the timing of the reset signal RST, the scan signal S(N), and the enabling signal EM of FIG. 2. The operation mode of the electronic circuit 200 is similar to the operation mode of the electronic circuit 100 and is not repeated here.

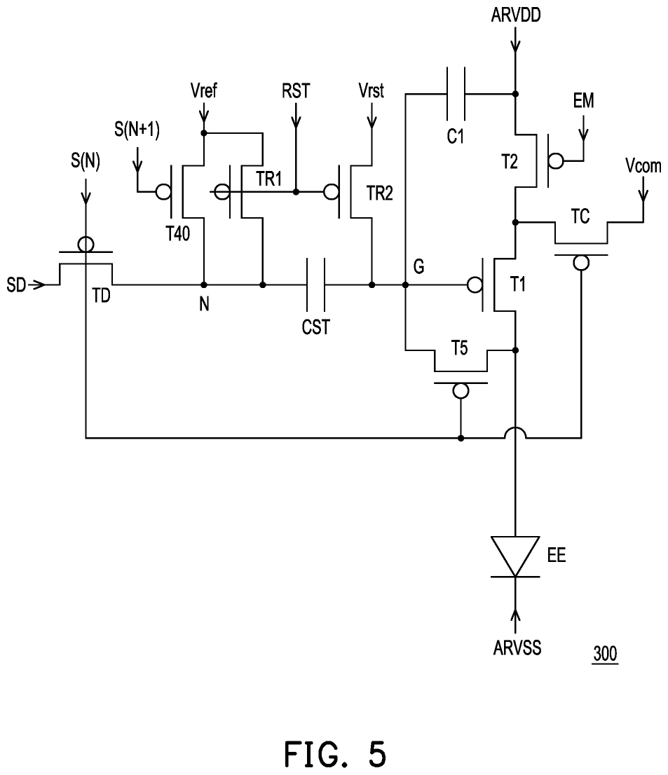

Please refer to FIG. 5. FIG. 5 is a schematic diagram of an electronic circuit shown according to the third embodiment of the disclosure. In the present embodiment, an electronic circuit 300 includes the electronic element EE, the driving transistor T1, the emitting transistor T2, the data transistor TD, a switching transistor T40, the compensation transistors T5 and TC, the reset transistors TR1 and TR2, and the capacitors C1 and CST. The implementation method of the electronic element EE, the driving transistor T1, the emitting transistor T2, the data transistor TD, the compensation transistor T5 and TC, the reset transistor TR2, and the capacitors C1 and CST is clearly explained in the embodiment of FIG. 1 and is therefore not repeated herein.

The second terminal of the reset transistor TR1 is coupled to the second terminal of the capacitor CST (i.e., the node N or an end point electrically connected to the node N). The gate terminal of the reset transistor TR1 receives the reset signal RST. One difference from the electronic circuit 200 is that the first terminal of the reset transistor TR1 is coupled to the reference voltage Vref.

In addition, the first terminal of the switching transistor T40 is coupled to the reference voltage Vref. The second terminal of the switching transistor T40 is coupled to the capacitor CST. The gate terminal of the switching transistor T40 receives the scan signal S(N).

In the present embodiment, the driving transistor T1, the emitting transistor T2, the switching transistor T40, the data transistor TD, the compensation transistors T5 and TC, and the reset transistors TR1 and TR2 are implemented by P-type field-effect transistors respectively. However, the disclosure is not limited thereto.

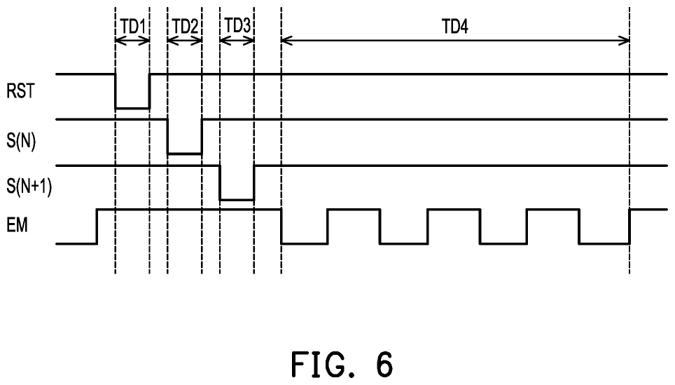

Please refer to both FIG. 5 and FIG. 6. FIG. 6 is a signal timing diagram shown according to the third embodiment. In the present embodiment, during the period TD1 (or reset period), the scan signal S(N), a scan signal S(N+1), and the enabling signal EM respectively have high voltage levels. The reset signal RST has a low voltage level. The reset transistors TR1 and TR2 are turned on. The emitting transistor T2, the switching transistor T40, the data transistor TD, and the compensation transistors T5 and TC are turned off. Therefore, the voltage value at the first terminal of the capacitor CST (i.e., the node G or an end point electrically connected to the node G) is substantially equal to the voltage value of the reset voltage Vrst. The voltage value at the second terminal of the capacitor CST (i.e., the node N or an end point electrically connected to the node N) is substantially equal to the voltage value of the reference voltage Vref.

During the period TD2 (or data input period), the reset signal RST, the scan signal S(N+1), and the enabling signal EM respectively have high voltage levels. The scan signal S(N) has a low voltage level. The data transistor TD and the compensation transistors T5 and TC are turned on. The reset transistors TR1 and TR2, the emitting transistor T2, and the switching transistor T40 are turned off. Therefore, the voltage value at the second terminal of the capacitor CST (i.e., the node N or an end point electrically connected to the node N) is substantially equal to the voltage value of the data signal SD. The electronic circuit 100 changes the voltage value at the gate terminal of the driving transistor T1 using the voltage value of the data signal SD based on the capacitive coupling of the capacitor CST. Since the compensation transistor T5 is turned on, the voltage value at the second terminal of the driving transistor T1 is substantially equal to the voltage value at the gate terminal of the driving transistor T1.

In addition, the voltage value at the first terminal of the driving transistor T1 is substantially equal to the voltage value of the common voltage Vcom. Therefore, the voltage difference value VSG between the voltage value at the first terminal (i.e., the source electrode) of the driving transistor T1 and the voltage value located at the gate terminal of the driving transistor T1 is determined. It should also be noted that during the period TD2, the power voltage ARVDD is changed due to the load change in the adjacent electronic circuit 100 or the load change in other electronic circuits. Compared with the power voltage ARVDD, the common voltage Vcom is relatively stable. Therefore, the electronic circuit 100 may provide a relatively stable voltage difference value VSG to the driving transistor T1 during the period TD2.

During the period TD3 (or compensation period), the reset signal RST, the scan signal S(N), and the enabling signal EM respectively have high voltage levels. The scan signal S(N+1) has a low voltage level. The switching transistor T40 is turned on. The data transistor TD, the compensation transistors T5 and TC, the reset transistors TR1 and TR2, and the emitting transistor T2 are turned off. The voltage value at the first terminal of the capacitor CST (i.e., the node G or an end point electrically connected to the node G) is coupled. The first terminal of the capacitor CST (i.e., the node G or an end point electrically connected to the node G) generates a new voltage value according to the voltage value stored during the period TD2 and the voltage value of the reference voltage Vref.

During a period TD4 (or driving period), the reset signal RST, the scan signal S(N), and the scan signal S(N+1) respectively have high voltage levels. The enabling signal EM has a duty cycle. The emitting transistor T2 performs a switching operation based on the duty cycle. The data transistor TD, the reset transistors TR1 and TR2, the switching transistor T40, and the compensation transistors T5 and TC are turned off. Therefore, the driving transistor T1 drives the electronic element EE during the period TD4 using the power voltage ARVDD and the voltage value at the gate terminal of the driving transistor T1.

It should be noted that during the period TD4, the second terminal of the capacitor CST (i.e., the node N or an end point electrically connected to the node N) receives the power voltage ARVDD. When the power voltage ARVDD is decreased, the voltage value at the first terminal of the driving transistor T1 is decreased. The voltage value at the gate terminal of the driving transistor T1 is also decreased. When the power voltage ARVDD is increased, the voltage value at the first terminal of the driving transistor T1 is increased. The voltage value at the gate terminal of the driving transistor T1 is also increased. Therefore, the voltage difference value VSG of the driving transistor T1 is not affected by the change in the power voltage ARVDD.

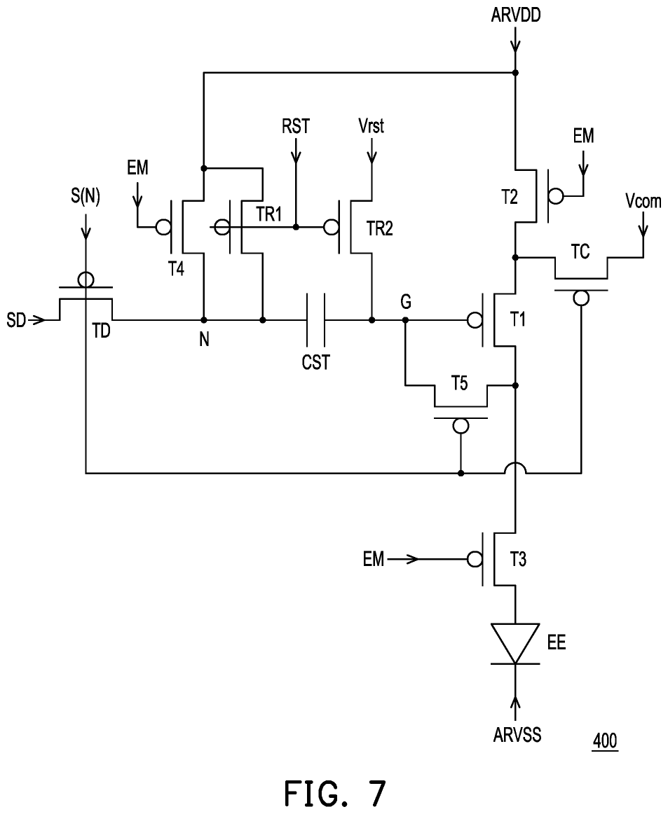

Please refer to FIG. 7. FIG. 7 is a schematic diagram of an electronic circuit shown according to the fourth embodiment. In the present embodiment, an electronic circuit 400 includes the electronic element EE, the driving transistor T1, the emitting transistors T2, T3, and T4, the data transistor TD, the compensation transistors T5 and TC, the reset transistors TR1 and TR2, and the capacitor CST. The first terminal of the emitting transistor T2 is coupled to the power voltage ARVDD. The second terminal of the emitting transistor T2 is coupled to the first terminal of the driving transistor T1. The first terminal of the capacitor CST (i.e., the node G or an end point electrically connected to the node G) is coupled to the gate terminal of the driving transistor T1. The first terminal of the emitting transistor T3 is coupled to the second terminal of the driving transistor T1. The second terminal of the emitting transistor T3 may be coupled to the anode of the electronic element EE. The cathode of the electronic element EE may be coupled to the power voltage ARVSS. The gate terminal of the emitting transistor T2 and the gate terminal of the emitting transistor T3 receive the enabling signal EM. Therefore, the emitting transistor T2 and the emitting transistor T3 may perform a switching operation synchronously in response to the duty cycle of the enabling signal EM. Therefore, the power voltage ARVDD may drive the electronic element EE via the driving transistor T1, the emitting transistor T2 and the emitting transistor T3.

The first terminal of the emitting transistor T4 is coupled to the power voltage ARVDD. The second terminal of the emitting transistor T4 is coupled to the capacitor CST. Furthermore, the second terminal of the emitting transistor T4 is coupled to the second terminal of the capacitor CST. The gate terminal of the transmitting transistor T4 receives the enabling signal EM.

The first terminal of the capacitor CST is coupled to the gate terminal of the driving transistor T1. When the electronic element EE is driven based on the power voltage ARVDD, the second terminal of the capacitor CST (i.e., the node N or an end point electrically connected to the node N) receives the power voltage ARVDD. When the power voltage ARVDD is changed, the voltage value at the gate terminal of the driving transistor T1 is also changed with the change in the power voltage ARVDD. Therefore, the voltage difference value between the first terminal of the driving transistor T1 and the gate terminal of the driving transistor T1 (the voltage difference value VSG of FIG. 1) is not affected by the change in the power voltage ARVDD.

The data transistor TD and the second terminal of the compensation transistor T5 are coupled to the gate terminal of the driving transistor T1. The implementation method of the compensation transistors T5 and TC and the reset transistors TR1 and TR2 is clearly explained in the embodiment of FIG. 1 and is therefore not repeated here.

In the present embodiment, the emitting transistor T3 is implemented by a P-type field-effect transistor, but the disclosure is not limited thereto.

In the present embodiment, the electronic circuit 400 may be adapted to the signal timing diagram shown in FIG. 2. In some embodiments, based on usage requirements, the emitting transistor T2 in FIG. 7 may also be omitted, but the disclosure is not limited thereto.

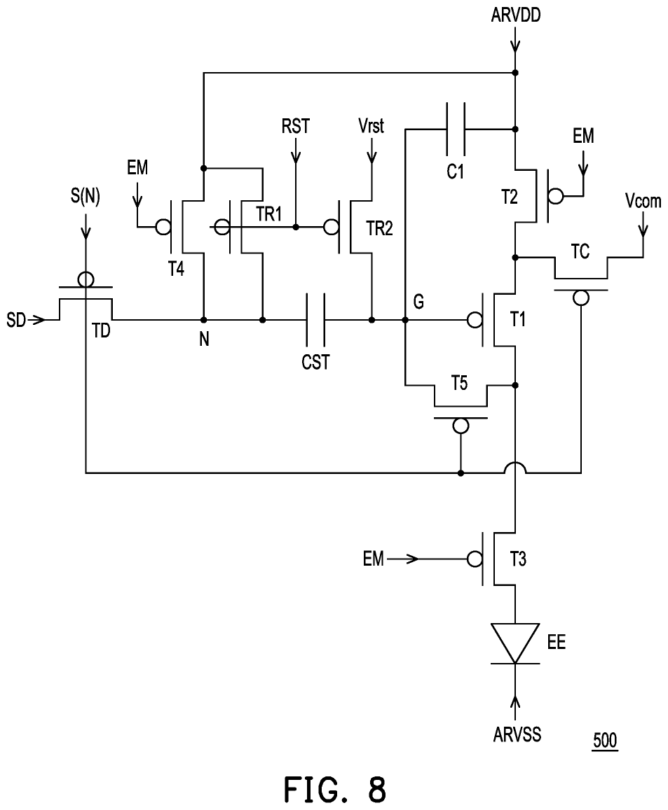

FIG. 8 is a schematic diagram of an electronic circuit shown according to the fifth embodiment. In the present embodiment, an electronic circuit 500 includes the electronic element EE, the driving transistor T1, the emitting transistors T2, T3, and T4, the data transistor TD, the compensation transistors T5 and TC, the reset transistors TR1 and TR2, and the capacitors CST and C1. The implementation method of the electronic element EE, the driving transistor T1, and the emitting transistors T2, T3, and T4 is clearly explained in the embodiment of FIG. 7 and is not repeated here. The implementation method of the data transistor TD, the compensation transistors T5 and TC, the reset transistors TR1 and TR2, and the capacitors CST and C1 is clearly explained in the embodiments of FIG. 1 and FIG. 3 and is therefore not repeated here.

In the present embodiment, the first terminal of the capacitor C1 is coupled to receive the power voltage ARVDD. The second terminal of the capacitor C1 is coupled to the gate terminal of the driving transistor T1. Therefore, when the power voltage ARVDD is decreased, the voltage values at two terminals of the capacitor C1 are both decreased. When the power voltage ARVDD is increased, the voltage values at two terminals of the capacitor C1 are both increased. Therefore, the voltage difference value VSG of the driving transistor T1 is not affected by the change in the power voltage ARVDD.

In the present embodiment, the electronic circuit 500 may be adapted to the signal timing diagram shown in FIG. 4. In some embodiments, based on usage requirements, the emitting transistor T2 in FIG. 8 may also be omitted, but the disclosure is not limited thereto.

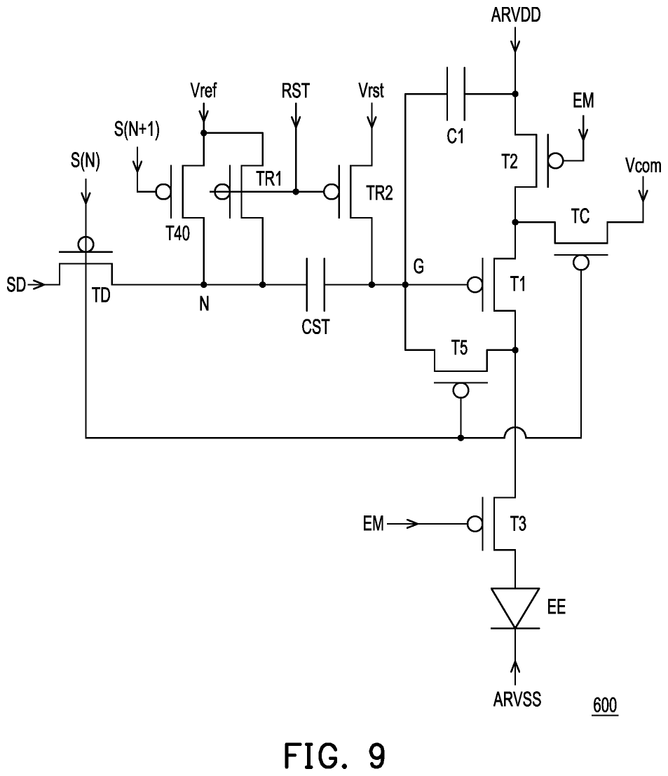

FIG. 9 is a schematic diagram of an electronic circuit shown according to the sixth embodiment. In the present embodiment, an electronic circuit 600 includes the electronic element EE, the driving transistor T1, the emitting transistors T2 and T3, the data transistor TD, the switching transistor T40, the compensation transistors T5 and TC, the reset transistors TR1 and TR2, and the capacitors C1 and CST. The implementation method of the electronic element EE, the driving transistor T1, and the emitting transistors T2, T3, and T4 is clearly explained in the embodiment of FIG. 7 and is not repeated here. The implementation method of the data transistor TD, the compensation transistors T5 and TC, the reset transistor TR1, and the capacitor CST is clearly explained in the embodiment of FIG. 1 and is therefore not repeated here.

In the present embodiment, the second terminal of the reset transistor TR1 is coupled to the second terminal of the capacitor CST. The gate terminal of the reset transistor TR1 receives the reset signal RST. The difference from the electronic circuit 200 is that the first terminal of the reset transistor TR1 is coupled to the reference voltage Vref. In addition, the first terminal of the switching transistor T40 is coupled to the reference voltage Vref. The second terminal of the switching transistor T40 is coupled to the capacitor CST. The gate terminal of the switching transistor T40 receives the scan signal S(N).

In the present embodiment, the electronic circuit 600 may be adapted to the signal timing diagram shown in FIG. 6. In some embodiments, based on usage requirements, the emitting transistor T2 in FIG. 9 may also be omitted, but the disclosure is not limited thereto.

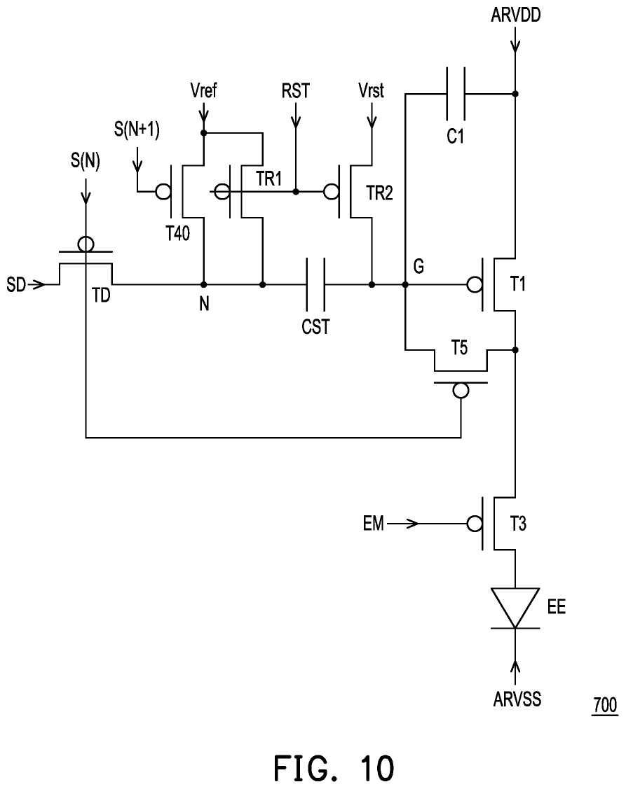

FIG. 10 is a schematic diagram of an electronic circuit shown according to the seventh embodiment. In the present embodiment, an electronic circuit 700 includes the electronic element EE, the driving transistor T1, the emitting transistor T3, the data transistor TD, the switching transistor T40, the compensation transistor T5, the reset transistors TR1 and TR2, and the capacitors C1 and CST. Compared with the electronic circuit 600, the electronic circuit 700 reduces the compensation transistor TC and the emitting transistor T2. In the present embodiment, the electronic circuit 600 may be adapted to the signal timing diagram shown in FIG. 6.

Generally, the electronic element EE is considered a load. Therefore, in different periods (the periods TD1 to TD4 as shown in FIG. 6), the power voltage ARVDD fluctuates in response to the operating conditions of the electronic element EE. Therefore, the power voltage ARVDD received by the electronic circuit 700 also fluctuates according to the operating conditions of the electronic element of the adjacent electronic circuit.

The electronic circuit 700 of the present embodiment further includes the emitting transistor T3. When the enabling signal EM has a high voltage level, the emitting transistor T3 is turned off. The emitting transistor T3 isolates the connection between the driving transistor T1 and the electronic element EE. Therefore, when the electronic element EE in the electronic circuit 700 is not driven, other elements in the electronic circuit 700 other than the emitting transistor T3 and the electronic element EE may not affect each other.

Based on the description of FIG. 10, it should be understood that in the embodiments of FIG. 7 and FIG. 8, the compensation transistor TC and the emitting transistor T2 in the electronic circuits 400 and 500 may also be omitted based on usage requirements. Moreover, in some embodiments, base on usage requirements, at least one of the electronic circuits 400, 500, 600, 700, the data transistor TD, the compensation transistor T5 and TC, and the reset transistor TR1 and TR2 may be omitted.

Based on the above, the first terminal of the at least one capacitor may be coupled to the gate terminal of the driving transistor. When the electronic element is driven, the second terminal of the at least one capacitor may receive the power voltage. Therefore, when the power voltage is changed, the voltage value at the gate terminal of the driving transistor is also changed with the change in the power voltage. The switching state of the driving transistor may be not affected by the change in the power voltage. In this way, the operation of the electronic element may be relatively stable when the power voltage is changed. Furthermore, during data input, the voltage value at the first terminal of the driving transistor is substantially equal to the voltage value of the common voltage. Compared with the power voltage, the common voltage is relatively stable. Therefore, the electronic circuit may provide a relatively stable voltage value to the first terminal of the driving transistor during data input.

Lastly, it should be mentioned that: each of the above embodiments is used to describe the technical solutions of the disclosure and is not intended to limit the disclosure; and although the disclosure is described in detail via each of the above embodiments, those having ordinary skill in the art should understand that: modifications may still be made to the technical solutions recited in each of the above embodiments, or portions or all of the technical features thereof may be replaced to achieve the same or similar results; the modifications or replacements do not make the nature of corresponding technical solutions depart from the scope of the technical solutions of each of the embodiments of the disclosure.

What is claimed is:

1. An electronic circuit, comprising:
an electronic element;
a driving transistor, wherein a power voltage is used to drive the electronic element via the driving transistor;
a first emitting transistor, wherein a first terminal of the first emitting transistor is coupled to the power voltage, and a second terminal of the first emitting transistor is coupled to the driving transistor; and
at least one capacitor, wherein a first terminal of the at least one capacitor is coupled to a gate terminal of the driving transistor,
wherein when the electronic element is driven, a second terminal of the at least one capacitor receives the power voltage.

2. The electronic circuit of claim 1, further comprising:
a second emitting transistor, wherein a first terminal of the second emitting transistor is coupled to the electronic element, and a second terminal of the second emitting transistor is coupled to the driving transistor.

3. The electronic circuit of claim 2, wherein a gate terminal of the second emitting transistor receives an enabling signal.

4. The electronic circuit of claim 1, further comprising:
a third emitting transistor, wherein a first terminal of the third emitting transistor is coupled to the power voltage, and a second terminal of the third emitting transistor is coupled to the at least one capacitor.

5. The electronic circuit of claim 4, wherein a gate terminal of the third emitting transistor receives an enabling signal.

6. The electronic circuit of claim 1, further comprising:
a switching transistor, wherein a first terminal of the switching transistor is coupled to a reference voltage, a second terminal of the switching transistor is coupled to the at least one capacitor, and a gate terminal of the switching transistor receives a scan signal.

7. The electronic circuit of claim 1, further comprising:
a data transistor, wherein a first terminal of the data transistor receives a data signal, a second terminal of the data transistor is coupled to the at least one capacitor, and a gate terminal of the data transistor receives a scan signal.

8. The electronic circuit of claim 1, further comprising:
a compensation transistor, wherein a first terminal of the compensation transistor receives a common voltage, a second terminal of the compensation transistor is coupled to the second terminal of the first emitting transistor, and a gate terminal of the compensation transistor receives a scan signal.

9. The electronic circuit of claim 1, further comprising:
a first reset transistor, wherein a first terminal of the first reset transistor is coupled to the power voltage, and a second terminal of the first reset transistor is coupled to the second terminal of the at least one capacitor.

10. The electronic circuit of claim 9, wherein a gate terminal of the first reset transistor receives a reset signal.

11. The electronic circuit of claim 9, further comprising:
a second reset transistor, wherein a first terminal of the second reset transistor is coupled to a reset voltage, and a second terminal of the second reset transistor is coupled to the first terminal of the at least one capacitor.

12. The electronic circuit of claim 11, wherein a gate terminal of the second reset transistor receives a reset signal.

13. An electronic circuit, comprising:
an electronic element;
a driving transistor, wherein a first terminal of the driving transistor is coupled to a power voltage, and the power voltage is used to drive the electronic element via the driving transistor;
a first emitting transistor, wherein a first terminal of the first emitting transistor is coupled to a second terminal of the driving transistor, and a second terminal of the first emitting transistor is coupled to the electronic element; and
at least one capacitor, wherein a first terminal of the at least one capacitor is coupled to a gate terminal of the driving transistor,
wherein when the electronic element is driven, a second terminal of the at least one capacitor receives the power voltage.

14. The electronic circuit of claim 13, wherein a gate terminal of the first emitting transistor receives an enabling signal.

15. The electronic circuit of claim 13, further comprising:
a second emitting transistor, wherein a first terminal of the second emitting transistor is coupled to the power voltage, and a second terminal of the second emitting transistor is coupled to the at least one capacitor.

16. The electronic circuit of claim 15, wherein a gate terminal of the second emitting transistor receives an enabling signal.

17. The electronic circuit of claim 13, further comprising:
a switching transistor, wherein a first terminal of the switching transistor is coupled to a reference voltage, a second terminal of the switching transistor is coupled to the at least one capacitor, and a gate terminal of the switching transistor receives a scan signal.

18. The electronic circuit of claim 13, further comprising:
a first reset transistor, wherein a first terminal of the first reset transistor is coupled to the power voltage, and a second terminal of the first reset transistor is coupled to the second terminal of the at least one capacitor.

19. The electronic circuit of claim 18, wherein a gate terminal of the first reset transistor receives a reset signal.

20. The electronic circuit of claim 18, further comprising:
a second reset transistor, wherein a first terminal of the second reset transistor is coupled to a reset voltage, and a second terminal of the second reset transistor is coupled to the first terminal of the at least one capacitor.
